(19) United States
(12) Patent Application Publication
(10) Pub. No.: US 2021/0359141 A1
(43) Pub. Date: Nov. 18, 2021

(54) ARRAY SUBSTRATE, METHOD FOR FORMING ARRAY SUBSTRATE, AND DISPLAY DEVICE

(71) Applicant: Shenzhen China Star Optoelectronics Semiconductor Display Technology Co., Ltd., Shenzhen (CN)

(72) Inventor: Xueru MEI, Shenzhen (CN)

(73) Assignee: Shenzhen China Star Optoelectronics Semiconductor Display Technology Co., Ltd., Shenzhen (CN)

(21) Appl. No.: 16/620,513

(22) PCT Filed: Nov. 5, 2019
(86) PCT No.: PCT/CN2019/115594

§ 371 Date: Dec. 8, 2019

(30) Foreign Application Priority Data
Oct. 8, 2019 (CN) 201910950381.2

(51) Int. Cl. H01L 29/786; H01L 27/12; H01L 29/16; H01L 29/24; H01L 29/267; H01L 29/76; H01L 21/02; H01L 29/66

(52) U.S. Cl. CPC H01L 29/78696; H01L 27/1222; H01L 27/124; H01L 29/1606; H01L 29/24; H01L 29/66045; H01L 29/7606; H01L 29/78687; H01L 27/127; H01L 21/02527; H01L 21/02568; H01L 29/267

(57) ABSTRACT

An array substrate, a method for forming an array substrate, and a display device are provided. The array substrate includes a substrate, and a gate layer, an active layer, and a source/drain layer formed over the substrate. An insulating layer is formed between the gate layer and the active layer, and the source/drain layer, and the active layer comprises at least one graphene layer and at least one molybdenum disulfide layer disposed in a stack, and the at least one graphene layer is located at a side away from the substrate of the active layer and contacts the source/drain layer.

### FIELD OF INVENTION

The present invention relates to the field of display technology, and more particularly, to an array substrate, a method for forming the array substrate, and a display device

### BACKGROUND

With the development of new display technologies such as flexible display, micro LED (μLED) display, and organic light-emitting diode (OLED) display, performance requirements for important driving components, such as high mobility, fast drive, low loss, etc., are becoming higher and higher.

Thin film transistor (TFT) array substrates are important driving components in various display technologies, and their performance is directly related to display effect of new display technologies. As the most important component of the thin film transistor array substrate, an active layer has great influence on the performance of the thin film transistor array substrate.

### Technical Problem

In the prior art, a semiconductor material such as amorphous germanium (a-Si) or low temperature polycrystalline germanium (LTPS) is generally used as a material of an active layer, and improvements in carrier mobility of such active material to the active layer are limited, resulting in lower performance of thin film transistor array substrate and inability to meet requirements of new display technology.

### Technical Solution

The present application provides an array substrate, a method for forming an array substrate, and a display device, which are intended to improve the structure of the array substrate, improve carrier concentration and mobility of an active layer on the array substrate, and thereby improve performance of the array substrate.

The present application provides an array substrate, comprising a substrate, and a gate layer, an active layer, and a source/drain layer formed over the substrate, wherein an insulating layer is formed between the gate layer and the active layer, and the source/drain layer, and the active layer comprises at least one graphene layer and at least one molybdenum disulfide layer disposed in a stack, and the at least one graphene layer is located at a side away from the substrate of the active layer and contacts the source/drain layer.

In some embodiments, the active layer comprises two graphene layers and the molybdenum disulfide layer disposed between the two graphene layers.

In some embodiments, the molybdenum disulfide layer comprises a single molybdenum disulfide layer in a number not more than three.

In some embodiments, the graphene layer comprises carbon layers in a number not greater than 10.

In some embodiments, the insulating layer comprises a gate insulating layer, and the gate layer, the gate insulating layer, and the active layer are sequentially formed over the substrate, wherein the source/drain layer is formed over the active layer and the gate insulating layer.

In some embodiments, a passivation layer is formed over the source/drain layer, and an indium tin oxide layer is formed over the passivation layer.

In some embodiments, the insulating layer comprises gate insulating layer and an interlayer dielectric layer, and the active layer, the gate insulating layer, and the gate layer are sequentially formed above the substrate, wherein the interlayer dielectric layer is formed over the active layer and the gate layer, and the source/drain layer is formed over the interlayer dielectric layer and passes through the interlayer dielectric layer to contact the active layer.

In some embodiments, a passivation layer is further formed over the source/drain layer and the interlayer dielectric layer, and an indium tin oxide layer is formed over the passivation layer.

The present application further provides a method for forming an array substrate, comprising:

providing a substrate;

forming a gate layer over the substrate;

forming a gate insulating layer over the substrate, covering the gate layer;

forming at least one graphene layer and at least one molybdenum disulfide layer in a stack over the gate insulating layer, and the at least one graphene layer is located at a side away from the substrate; and

forming source/drain layer over the gate insulating layer and the active layer.

In some embodiments, forming the at least one graphene layer and the at least one molybdenum disulfide layer in a stack over the gate insulating layer, comprising sequentially forming a first graphene layer, the at least one molybdenum disulfide layer, and a second graphene layer to form the active layer.

In some embodiments, after forming the source/drain layer over the gate insulating layer and the active layer, further comprising forming a passivation layer over the source/drain layer, and forming a via hole over the passivation layer, and the via hole extends from a top surface of the passivation layer to an upper surface of the source/drain layer.

In some embodiments, after forming the passivation layer over the source/drain layer, further comprising forming an indium tin oxide (ITO) layer over the passivation layer, and the ITO layer passes through the via hole of the passivation layer and contacts the source/drain layer.

The present application further provides a display device, wherein the display device comprises the array substrate described above, and the array substrate comprising a substrate and a gate layer, an active layer, and a source/drain layer formed over the substrate, wherein an insulating layer is formed between the gate layer and the active layer, and the source/drain layer, and the active layer comprises at least one graphene layer and at least one molybdenum disulfide layer disposed in a stack, and the at least one graphene layer is located at a side away from the substrate of the active layer and contacts the source/drain layer.

In some embodiments, the active layer comprises two graphene layers and the molybdenum disulfide layer disposed between the two graphene layers.

In some embodiments, the molybdenum disulfide layer comprises a single molybdenum disulfide layer in a number not more than three.

In some embodiments, the graphene layer comprises carbon layers in a number not greater than 10.

In some embodiments, the insulating layer comprises a gate insulating layer, and the gate layer, the gate insulating layer, and the active layer are sequentially formed over the substrate, wherein the source/drain layer is formed over the active layer and the gate insulating layer.

In some embodiments, a passivation layer is formed over the source/drain layer, and an indium tin oxide layer is formed over the passivation layer.

In some embodiments, the insulating layer comprises a gate insulating layer and an interlayer dielectric layer, and the active layer, the gate insulating layer, and the gate layer are sequentially formed above the substrate, wherein the interlayer dielectric layer is formed over the active layer and the gate layer, and the source/drain layer is formed over the interlayer dielectric layer and passes through the interlayer dielectric layer to contact the active layer.

In some embodiments, a passivation layer is further formed over the source/drain layer and the interlayer dielectric layer, and an indium tin oxide layer is formed over the passivation layer.

### Advantageous Effects

In the present application, the active layer of the array substrate comprises the graphene layer and the molybdenum disulfide layer disposed in a stack, and the at least one graphene layer is located on a side of the active layer facing away from the substrate and is in contact with the source/drain layer of the array substrate. As a typical two-dimensional transition metal chalcogenide, molybdenum disulfide has the characteristics of adjustable band gap and greater carrier concentration, while graphene has high conductance, which can provide a large number of free electrons for molybdenum dioxide. By laminating the at least one graphene layer and the molybdenum disulfide layer together to form the active layer of the array substrate and locating the at least one graphene layer at a side of the active layer, facing away from the substrate and contacting the source/drain layer of the array substrate, the carrier mobility of the active layer is improved and the performance of the array substrate is improved. Meanwhile, the active layer has a greater carrier concentration and the interface barrier between the active layer and the source/drain layer is reduced.

### BRIEF DESCRIPTION OF DRAWINGS

To detailly explain the technical schemes of the embodiments or existing techniques, drawings that are used to illustrate the embodiments or existing techniques are provided. Obviously, the illustrated embodiments are merely part of the present disclosure. It is easy for any person having ordinary skill in the art to obtain other drawings without making inventive effort.

FIG. 1 is a schematic structural view of forming a gate layer over a substrate in an embodiment of an array substrate according to the present application.

FIG. 2 is a schematic structural diagram of forming a gate insulating layer in an embodiment of an array substrate according to the present application.

FIG. 3 is a schematic structural view showing an active layer formed in an embodiment of an array substrate according to the present application.

FIG. 4 is a schematic structural diagram of forming a source/drain layer in one embodiment of an array substrate according to the present application.

FIG. 5 is a schematic structural diagram of forming a passivation layer in an embodiment of an array substrate according to the present application.

FIG. 6 is a schematic structural view of forming an indium tin oxide layer in one embodiment of an array substrate according to the present application.

FIG. 7 is a schematic flowchart of another embodiment of a method for forming an array substrate according to the present application.

FIG. 8 is a schematic flowchart of an embodiment of a method for forming an array substrate according to the present application.

FIG. 9 is a schematic structural view of another embodiment of an array substrate according to the present application.

array substrate 10; array substrate 10a; substrate 11; substrate 11a; gate layer 12; gate layer 12a; gate insulating layer 13; gate insulating layer 13a; interlayer dielectric layer 14, active layer 15, active layer 15a; graphene layer 151; graphene layer 151a; molybdenum disulfide layer 152; molybdenum disulfide layer 152a; source/drain layer 16; source/drain layer 16a; passivation layer 17; passivation layer 17a; indium tin oxide layer 18; indium tin oxide layer 18a.

### DETAILED DESCRIPTION

To explain in detail the technical schemes of the embodiments or existing techniques, drawings that are used to illustrate the embodiments or existing techniques are provided. Obviously, the illustrated embodiments are merely part of the present disclosure. It is easy for any person having ordinary skill in the art to obtain other drawings without making inventive effort.

In the description of the present application, it is to be understood that the terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, etc. indicating orientation or positional relationship are based on the orientation or positional relationship shown in the drawings, and are merely for the convenience of the description of the present application and the simplification of the description. The above terms are not intended to indicate or imply that the device or component referred to has a specific orientation and constructed and operated in a specific orientation, and thus, are not to be construed as limiting the present application. Moreover, the terms “first” and “second” are used for descriptive purposes only and are not to be construed as indicating or implying a relative importance or implicitly indicating the number of technical features indicated. Thus, features defining “first” or “second” may include one or more of the described features either explicitly or implicitly. In the description of the present application, the meaning of “a plurality” is two or more unless specifically defined otherwise.

In the present application, the word “exemplary” is used to mean “serving as an example, instance, or illustration.” Any embodiment described in this application as “exemplary” is not necessarily to be construed as preferred or advantageous over other embodiments. To enable any person skilled in the art to make and use the application, the following description is presented. In the following description, details are set forth for the purpose of explanation. It should be understood that those skilled in the art will recognize that the present invention can be practiced without the specific details. In other instances, well-known structures and procedures are not described in detail to avoid unnecessary detail. Therefore, the application is not intended to be limited to the shown embodiments, but is in accord with the broad scope of the principles and features disclosed herein.

The application provides an array substrate. The details are further described below.

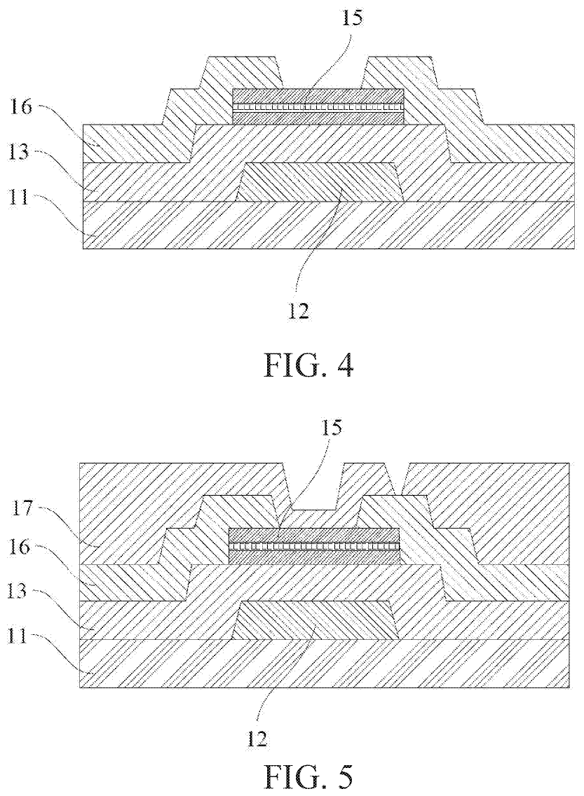

Referring to FIG. 4, an array substrate 10 comprises a substrate 11, and a gate layer 12, an active layer 15 and a source/drain layer 16 which are formed over the substrate 11. An insulating layer is formed between the gate layer 12 and the active layer 15, and the source/drain layer 16. The source/drain layer 16 comprises a source and a drain connected to both sides of the active layer 15. The source, the drain and the active layer 15 are separated from the gate layer 12 by the insulating layer. The number and structure of the insulating layer are specifically depending on the arrangement of the gate layer 12, the active layer 15 and the source/drain layer 16 over the substrate 11, and the structure of the insulating layer will be described in detail below but not be described herein.

In one embodiment, as shown in FIG. 3, the active layer 15 may comprise a graphene layer 151 and a molybdenum disulfide (MoS₂) layer 152 disposed in a stack, wherein at least one graphene layer 151 is located at a side away from the substrate 11 of the active layer and contacts the source/drain layer 16.

It is noted that as a typical two-dimensional transition metal chalcogenide, molybdenum disulfide has the characteristics of adjustable band gap and high carrier concentration, and graphene has high conductance, which can provide a large number of free electrons for molybdenum dioxide. By laminating the graphene layer 151 and the molybdenum disulfide layer 152 together to form an active layer 15 of the array substrate 10 and making at least one graphene layer 151 being located at a side of the active layer 15 facing away from the substrate 11 and contacts the source/drain layer 16 of the array substrate, the carrier mobility of the active layer 15 is improved and the performance of the array substrate 10 is improved. Meanwhile, the active layer 15 has a higher carrier concentration and the interface barrier between the active layer 15 and the source/drain layer 16 is reduced.

Moreover, graphene and molybdenum disulfide have greater mechanical strength, and structural strength of the active layer 15 can be improved by laminating the at least one graphene layer 151 and the molybdenum disulfide layer 152 together to form the active layer 15 of the array substrate 10, so that the array substrate 10 can be more suitable for a flexible display device.

In some embodiments, the active layer 15 may comprise two graphene layers 151 and the molybdenum disulfide layer 152 between the two graphene layers 151 to ensure that the active layer 15 has better carrier mobility rate and mechanical properties, and at the same time, the structure and manufacturing process for forming the same are relatively simple.

Of course, the graphene layer 151 and the molybdenum disulfide layer 152 in the active layer 15 may also be one or more layers. For example, the active layer 15 may comprise the graphene layer 151 and the molybdenum disulfide layer 152, and the graphene layer 151 is located above the molybdenum disulfide layer 152. Alternatively, the active layer 15 comprises a plurality of graphene layers 151 and a plurality of molybdenum disulfide layers, 152 which are alternatively and sequentially spaced apart, and the topmost layer of the active layer 15 is the graphene layer 151.

In one embodiment, the molybdenum disulfide layer 152 may comprise a single layer of molybdenum disulfide in a number not more than 3, such that the molybdenum disulfide layer 152 has a greater carrier concentration, and at the same time, reduces the formation of the molybdenum disulfide layer 152 and lowers the overall thickness of the array substrate 10.

Of course, the number of the single molybdenum disulfide layer in the molybdenum disulfide layer 152 may also be greater than 3, depending on the performance requirements of the array substrate 10.

In an embodiment, the graphene layer 151 may comprise carbon layers in a number not greater than 10 to effectively reduce the interface barrier between the active layer 15 and the source/drain layer 16 while reducing the time for forming the graphene layer 151, and reduce the overall thickness of the array substrate 10. The number of carbon layers in the graphene layer 151 may specifically be one layer, two layers, five layers, and the like, and is not limited herein.

In one embodiment, as shown in FIG. 4, the insulating layer may comprise a gate insulating layer 13. The gate layer 12, the gate insulating layer 13, and the active layer 15 are sequentially formed over the substrate 11, and the source/drain layer 16 is formed over the active layer 15 and the gate insulating layer 13. The source/drain layer 16 has a source and a drain that respectively contacts both sides of the active layer 15. The gate insulating layer 13 covers the gate layer 12 to prevent the gate layer 12 from contacting the active layer 15.

In some embodiments, a material of the gate insulating layer 13 may be silicon oxide (SiOx); or a composite layer composed of a combination of silicon oxide (SiOx) and silicon nitride (SiNx); or a composite layer composed of a combination of silicon nitride (SiNx), silicon oxide (SiOx), and silicon oxynitride (SiNO); or a composite layer of silicon nitride (SiNx), silicon oxide (SiOx), and aluminum oxide (Al₂O₃). In addition, the material of the gate insulating layer 13 may be a high-k dielectric layer such as aluminum nitride (AlN) or hafnium oxide (HfO₂).

In one embodiment, the substrate 11 is a transparent substrate. Specifically, the substrate 11 may be a transparent glass substrate, or a transparent flexible substrate made of a material such as polyimide (PI), polyethylene terephthalate (PET), cyclo-olefin polymer (COC), polyethersulfone resin (PES), or the like.

In one embodiment, the material of the gate layer 12 may be a composite layer of laminated molybdenum and copper, or a composite layer of laminated molybdenum and aluminum.

In one embodiment, the material of the source/drain layer 16 may be a metal material such as copper, aluminum, or cobalt, a composite layer of laminated molybdenum and copper, or a composite layer of laminated molybdenum and aluminum.

As shown in FIG. 5, a passivation layer (PV) layer may be formed over the source/drain layer 16, and a via hole is formed in the passivation layer 17, and the via hole extends from the top surface of the passivation layer 17 to the upper surface of the source/drain layer 16. The material of the passivation layer 17 may be insulating materials such as silicon nitride (SiNx), silicon oxide (SiOx), silicon oxynitride (SiNO), aluminum oxide (Al₂O₃), hafnium oxide (HfO₂), or boron nitride (BN).

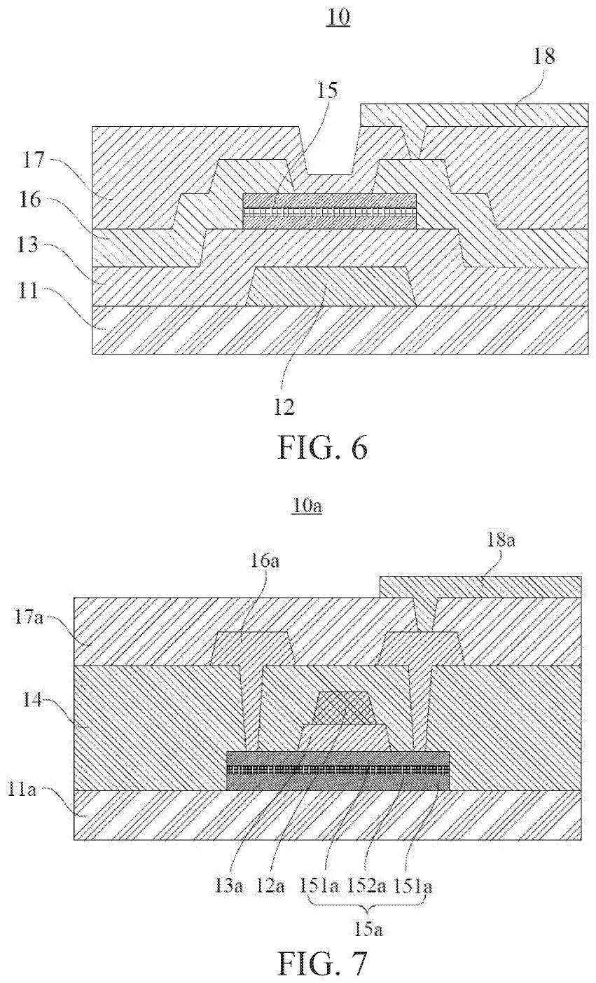

As shown in FIG. 6, an indium tin oxide (ITO) layer may be formed over the passivation layer 17 and is patterned to form the pixel electrode. The ITO layer 18 contacts the source/drain layer 16 through the via holes in the passivation layer 17.

In another embodiment, as shown in FIG. 7, the insulating layer of the array substrate 10a comprises a gate insulating layer 13a and an interlayer dielectric layer 14. The active layer 15a of the array substrate 10a, the gate insulating layer 13a, and the gate layer 12a are sequentially formed on the substrate 11a, and the gate insulating layer 13a is located between the active layer 15a and the gate layer 12a to separate the active layer 15a and the gate layer 12a. The interlayer dielectric layer 14 is formed on the active layer 15a and the gate layer 12a, and the source/drain layer 16a is formed on the interlayer dielectric layer 14, so that the source/drain layer 16a and the gate layer 12a are separated to prevent the source/drain layer 16a from contacting the gate layer 12a, and the source/drain layer 16a contacts the active layer 15a through the interlayer dielectric layer 14.

In some embodiments, a passivation layer 17a is further formed over the source/drain layer 16a and the interlayer dielectric layer 14a, and an indium tin oxide layer 18a is further formed over the passivation layer 17a. The indium tin oxide layer 18a forms the pixel electrode after being patterned.

The active layer 15a, the gate insulating layer 13a, the gate layer 12a, the source/drain layer 16a, and the passivation layer 17a may comprise the same materials as the above active layer 15, the gate insulating layer 13, the gate layer 12, the source/drain layer 16, and the passivation layer 17, and will not be described herein.

A material of the interlayer dielectric layer 14 may be silicon nitride, silicon dioxide, or the like.

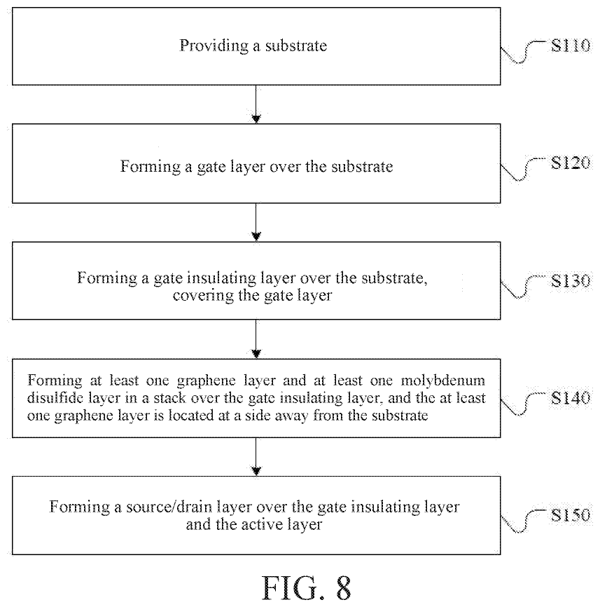

As shown in FIG. 8, the present application further provides a method for forming an array substrate, which comprises S110 to S150 but is not limited thereto, and detailed descriptions of steps S110 to S150 are as follows:

S110: Providing a substrate 11.

The substrate 11 is a transparent substrate 11, such as a glass substrate 11, a plastic substrate 11, or the like, and may also be a flexible substrate 11.

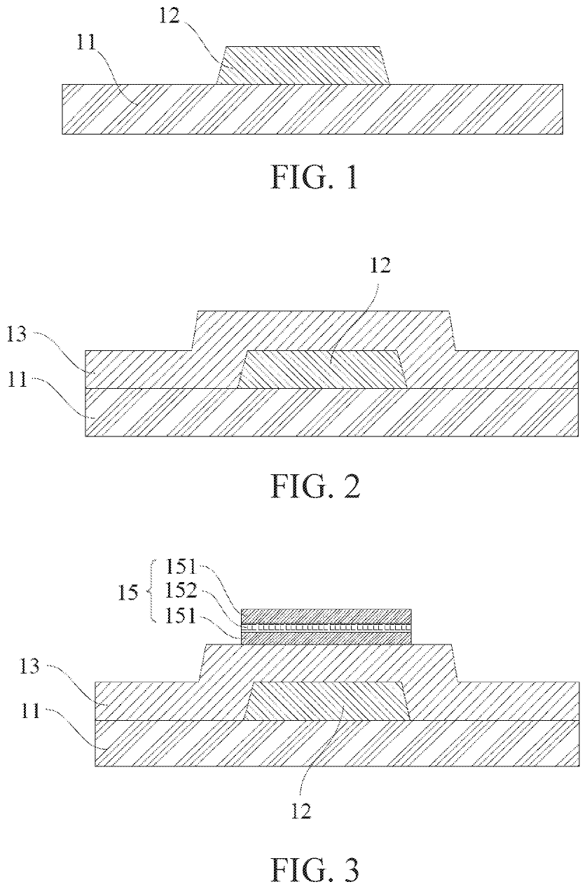

S120: As shown in FIG. 1, forming a gate layer 12 over the substrate 11.

The specific manufacturing process is as follows: depositing a metal layer over the substrate 11, and a material of the metal layer is a material of the gate layer 12. The metal layer is then patterned to form the gate layer 12 through a photomask process including steps such as photoresist coating, exposure, development, etching, and photoresist removal.

S130: As shown in FIG. 2, forming a gate insulating layer 13 covering the gate layer 12 over the substrate 11.

The step of forming the gate insulating layer 13 can refer to the step of forming the gate layer 12 described above, and details are not described herein again.

S140: As shown in FIG. 3, a graphene layer 151 and a molybdenum disulfide layer 152 are formed over the gate insulating layer 13 in a stack to form an active layer 15, and at least one graphene layer 151 is located at one side of the active layer 15 away from the substrate 11.

Both the graphene layer 151 and the molybdenum disulfide layer 152 can be formed by a solution method, a vapor phase deposition method, or a transfer technique. In the process of forming the graphene layer 151 and the molybdenum disulfide layer 152, the graphene layer 151 and the molybdenum disulfide layer 152 can be obtained in different number of layers by controlling conditions such as film formation time to adjust mobility of the active layer 15.

The above description of the structure of the active layer 15 may be referred to for the number and lamination method of the at least one graphene layer 151 and the molybdenum disulfide layer 152 in the active layer 15, and details are not described herein again.

S150: As shown in FIG. 4, forming a source/drain layer 16 over the gate insulating layer 13 and the active layer 15.

The step of forming the source/drain layer 16 may refer to the above step of forming the gate layer 12, and details are not described herein again.

In one embodiment, forming the graphene layer 151 and the molybdenum disulfide layer 152 in a stack over the gate insulating layer 13 to form the active layer 15 comprises:

Sequentially forming a first graphene layer, a molybdenum disulfide layer 152, and a second graphene layer over the gate insulating layer 13 to constitute the active layer 15. The first graphene layer is the graphene layer 151 located at the lower side of the molybdenum disulfide layer 152 in FIG. 3, and the first graphene layer is the graphene layer 151 located at the upper side of the molybdenum disulfide layer 152 in FIG. 3.

In some embodiments, after the source/drain layer 16 is formed over the gate insulating layer 13 and the active layer 15, the method may further comprise steps S160 and S170 as described in detail below:

S160: As shown in FIG. 5, forming a passivation layer 17 over the source/drain layer 16 and a via hole in the passivation layer 17. The via hole extends from the top surface of the passivation layer 17 to the upper surface of the source/drain layer 16.

S170: As shown in FIG. 6, forming an indium tin oxide layer 18 over the passivation layer 17, and the indium tin oxide layer 18 is patterned to form a pixel electrode. The indium tin oxide layer 18 passes through the via hole and the passivation layer 17 and contacts the source/drain layer 16.

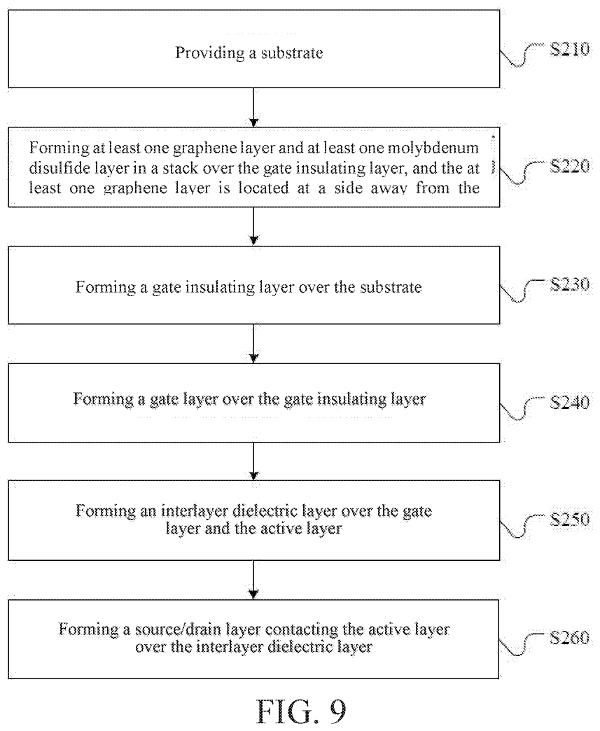

As shown in FIGS. 7-9, the present application further provides another method for forming an array substrate comprising S210 to S260 but not limited thereto, and detailed descriptions of steps S210 to S260 are as follows:

S210: providing a substrate 11a.

S220: forming a graphene layer 151a and a molybdenum disulfide layer 152a in stack over the substrate 11a to form the active layer 15a, and at least one graphene layer 151a is located at a side of the active layer 15a facing away from the substrate 11a.

S230: forming a gate insulating layer 13a over the active layer 15a.

S240: forming a gate layer 12a over the gate insulating layer 13a.

S250: forming an interlayer dielectric layer 14 over the gate layer 12a and the active layer 15a.

S260: forming a source/drain layer 16a contacting the active layer 15a over the interlayer dielectric layer 14.

In some embodiments, forming the graphene layer 151a and the molybdenum disulfide layer 152a in a stack over the substrate 11a to form the active layer 15a comprises:

Sequentially forming a first graphene layer, a molybdenum disulfide layer 152, and a second graphene layer over the substrate 11a to constitute the active layer 15a. The first graphene layer is the graphene layer 151a over the lower side of the molybdenum disulfide layer 152a in FIG. 7, and the first graphene layer is the graphene layer 151a over the upper side of the molybdenum disulfide layer 152a in FIG. 7.

In some embodiments, after forming the source/drain layer 16a contacting the active layer 15a over the interlayer dielectric layer 14, the method may further comprise steps S270 and S280 as described in detail below:

S270: forming a passivation layer 17a over the source/drain layer 16a and the interlayer dielectric layer 14, and forming a via hole in the passivation layer 17a extending from the top surface of the passivation layer 17a to the upper surface of the source/drain layer 16a.

S280: forming an indium tin oxide layer 18a over the passivation layer 17a, and the indium tin oxide layer 18a is then patterned to form a pixel electrode. The indium tin oxide layer 18a contacts the source/drain layer 16a through the via hole of the passivation layer 17a.

It can be understood that the array substrate obtained by the above two methods for forming an array substrate has an active layer comprising a graphene layer and a molybdenum disulfide layer in a stack, and the at least one graphene layer is located at a side away from the substrate of the active layer and contacts the source/drain layer away from the substrate of the active layer. The carrier mobility of the active layer and the performance of the array substrate are improved, while the active layer has a greater carrier concentration and the interface barrier between the active layer and the source/drain layer is reduced. Moreover, the structural strength of the active layer can be improved, so that the array substrate can be more suitable for a flexible display device.

It should be noted that, in the above-mentioned array substrate embodiment, only the above structure is described. It can be understood that, in addition to the above structure, the array substrate of the present application may further include any other necessary structures such as a buffer layer as needed and is not limited to the description.

The present application provides a display device, and the display device comprises the array substrate as described above, or an array substrate formed by the method for forming the array substrate as described above, and the specific structure of the array substrate refers to the above embodiment. Because the display device adopts all the technical solutions of all the above embodiments, it possesses at least all the beneficial effects brought by the technical solutions of the above embodiments which are not repeated herein.

The display device may be any display device having the above array substrate, such as a flexible display device, a micro light-emitting diode display device, an organic light-emitting diode display device, and the like, which is not limited herein.

The above describes an array substrate, a method for manufacturing an array substrate, and a display device provided by the present application. While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

1. An array substrate, comprising a substrate, and a gate layer, an active layer, and a source/drain layer formed over the substrate, wherein an insulating layer is formed between the gate layer and the active layer, and the source/drain layer, and the active layer comprises at least one graphene layer and at least one molybdenum disulfide layer disposed in a stack, and the at least one graphene layer is located at a side away from the substrate of the active layer and contacts the source/drain layer.

2. The array substrate of claim 1, wherein the active layer comprises two graphene layers and the molybdenum disulfide layer disposed between the two graphene layers.

3. The array substrate of claim 2, wherein the molybdenum disulfide layer comprises a single molybdenum disulfide layer in a number not more than three.

4. The array substrate of claim 3, wherein the graphene layer comprises carbon layers in a number not greater than 10.

5. The array substrate of claim 1, wherein the insulating layer comprises a gate insulating layer, and the gate layer, the gate insulating layer, and the active layer are sequentially formed over the substrate, wherein the source/drain layer is formed over the active layer and the gate insulating layer.

6. The array substrate of claim 5, wherein a passivation layer is formed over the source/drain layer, and an indium tin oxide layer is formed over the passivation layer.

7. The array substrate of claim 1, wherein the insulating layer comprises a gate insulating layer and an interlayer dielectric layer, and the active layer, the gate insulating layer, and the gate layer are sequentially formed above the substrate, wherein the interlayer dielectric layer is formed over the active layer and the gate layer, and the source/drain layer is formed over the interlayer dielectric layer and passes through the interlayer dielectric layer to contact the active layer.

8. The array substrate of claim 7, wherein a passivation layer is further formed over the source/drain layer and the interlayer dielectric layer, and an indium tin oxide layer is formed over the passivation layer.

9. A method for forming an array substrate, comprising:
providing a substrate;
forming a gate layer over the substrate;
forming a gate insulating layer over the substrate, covering the gate layer;
forming at least one graphene layer and at least one molybdenum disulfide layer in a stack over the gate insulating layer, and the at least one graphene layer is located at a side away from the substrate; and
forming a source/drain layer over the gate insulating layer and the active layer.

10. The method for forming the array substrate of claim 9, wherein forming the at least one graphene layer and the at least one molybdenum disulfide layer in a stack over the gate insulating layer comprises:
sequentially forming a first graphene layer, the molybdenum disulfide layer, and a second graphene layer to form the active layer.

11. The method for forming the array substrate of claim 9, wherein after forming the source/drain layer over the gate insulating layer and the active layer, further comprises:
forming a passivation layer over the source/drain layer, and forming a via hole over the passivation layer, and the via hole extends from a top surface of the passivation layer to an upper surface of the source/drain layer.

12. The method for forming the array substrate of claim 11, wherein after forming the passivation layer over the source/drain layer, further comprises:
forming an indium tin oxide (ITO) layer over the passivation layer, and the ITO layer passes through the via hole of the passivation layer and contacts the source/drain layer.

13. A display device, wherein the display device comprises an array substrate, and the array substrate comprises a substrate and a gate layer, an active layer, and a source/drain layer formed over the substrate, wherein an insulating layer is formed between the gate layer and the active layer, and the source/drain layer, and the active layer comprises at least one graphene layer and at least one molybdenum disulfide layer disposed in a stack, and the at least one graphene layer is located at a side away from the substrate of the active layer and contacts the source/drain layer.

14. The display device of claim 13, wherein the active layer comprises two graphene layers and the molybdenum disulfide layer disposed between the two graphene layers.

15. The display device of claim 14, wherein the molybdenum disulfide layer comprises a single molybdenum disulfide layer in a number not more than three.

16. The display device of claim 15, wherein the graphene layer comprises carbon layers in a number not greater than 10.

17. The display device of claim 13, wherein the insulating layer comprises a gate insulating layer, and the gate layer, the gate insulating layer, and the active layer are sequentially formed over the substrate, wherein the source/drain layer is formed over the active layer and the gate insulating layer.

18. The display device of claim 17, wherein a passivation layer is formed over the source/drain layer, and an indium tin oxide layer is formed over the passivation layer.

19. The display device of claim 13, wherein the insulating layer comprises a gate insulating layer and an interlayer dielectric layer, and the active layer, the gate insulating layer, and the gate layer are sequentially formed above the substrate, wherein the interlayer dielectric layer is formed over the active layer and the gate layer, and the source/drain layer is formed over the interlayer dielectric layer and passes through the interlayer dielectric layer to contact the active layer.

20. The display device of claim 19, wherein a passivation layer is further formed over the source/drain layer and the interlayer dielectric layer, and an indium tin oxide layer is formed over the passivation layer.
